(19) United States
(12) Patent Application Publication
(10) Pub. No.: US 2010/0059107 A1
(43) Pub. Date: Mar. 11, 2010

(54) PHOTOVOLTAIC SOLAR CELL AND METHOD OF MAKING THE SAME

(75) Inventors: Allen M. Barnett, Landenberg, PA (US); Jerome S. Culik, Nottingham, PA (US); David H. Ford, Elkton, MD (US)

Correspondence Address: KILYK & BOWERSOX, P.L.L.C., 400 HOLIDAY COURT, SUITE 102, WARRENTON, VA, 20186, US

(73) Assignee: BLUE SQUARE ENERGY INCORPORATED, North East, MD (US)

(21) Appl. No.: 12/066,960

(22) PCT Filed: Jul. 31, 2006
(86) PCT No.: PCT/US06/29834

§ 371 Date: Nov. 6, 2008

Related U.S. Application Data
(60) Provisional application No. 60/717,808, filed on Sep. 16, 2005.

(51) Int. Cl. H01L 31/00; H01L 21/027; H01L 31/18

(52) U.S. Cl. 136/255; 438/72; 136/256; 257/E31.002; 257/E21.023

(57) ABSTRACT

A front-surface-illuminated photovoltaic device, having a first semiconductor layer (180) with a back surface, a second semiconductor layer (130) with a front surface, the second layer (130) having the opposite doping type to the first layer (180) and deposited on the first layer (180); and at least one ohmic contact (160, 230) to each of the first (180) and second (130) semiconductor layers; and a process for making the photovoltaic device. The device may also have a barrier layer (190) for reducing diffusion of impurities from the first semiconductor layer (180) into the second semiconductor layer (130), a blocking layer (120), and a reflector layer (200). The device may have an array of first regions (115) in which the second layer (130) is of opposite doping type to that of the first layer (180) and forms p-n junctions (240) in these first regions (115), and second regions (300), each second region (300) containing the barrier layer (190) and the reflector layer (200). The first (130) and second (300) regions are laterally intermixed, have a lateral shape of either bounded regions or stripes, or a combination of bounded regions and stripes.

This application claims priority to U.S. Provisional Application 60/717,808 filed on Sep. 16, 2005.

### BACKGROUND OF THE INVENTION

Broadly speaking, the solar cell industry has followed two paths in its forty year history. Single-crystal and multicrystalline silicon solar cells have demonstrated high efficiency and long operating lifetimes, but have been prohibitively costly for many applications. Alternatively, low cost thin-film solar cell technologies, such as those based on amorphous silicon or other semiconductors such as CdTe, have the appealing features of reduced materials consumption and the potential for high-throughput production in thin-film coating processes. They are also amenable to monolithic array designs to drastically reduce costs of creating modules. Unfortunately, thin film solar cells have generally failed to demonstrate the efficiency or reliability of crystalline silicon solar cells.

The 1980s witnessed the first serious consideration of hybrid approaches, wherein thin-films of silicon are deposited on low-cost substrates, the purpose of which is to combine the high efficiency and reliability associated with crystalline silicon solar cells with the low-cost potential of thin-film deposition technology. This new thinking was bolstered by the realization that thin silicon solar cells that incorporate optical features using light trapping effects could not only ameliorate penalties in efficiency previously expected with thin silicon solar cells, but that the thin (<50 micron) device configuration was actually the best design for a silicon solar cell. U.S. Pat. No. 4,571,448, granted to A. M. Barnett in 1986, discloses a seminal design for a thin film photovoltaic solar cell on a low-cost substrate.

Many of the expected advantages of a thin silicon solar cell, such as high photogenerated currents due to light-trapping, high voltages due to higher doping levels, monolithic interconnection, reduced sensitivity to impurities and crystal defects, and enhanced gettering potential, have been demonstrated singularly in various experimental devices. However, the useful and synergistic combination of these features in a cost-effective, manufacturable production technology has eluded the industry. The formidable materials problems encountered in achieving this objective, specifically the difficulties in producing thin layers of high quality silicon on low-cost substrates, is the main technical hurdle.

### SUMMARY OF THE INVENTION

The disclosed photovoltaic device and method for making the device overcomes the previously mentioned problems in part by making use of thin films on relatively low cost substrates. Disclosed is a front-surface-illuminated photovoltaic device having a first semiconductor layer, or substrate, with a back surface; a second semiconductor layer with a front surface, the second layer being of opposite doping type to the first layer and deposited on the first layer; and at least one ohmic contact to each of the first and second semiconductor layers. The device may also have a barrier layer for reducing diffusion of impurities from the first semiconductor layer into the second semiconductor layer, and a reflector layer. The device may also have a semiconductor blocking layer. The blocking layer and barrier layer allow the use of less pure (hence less expensive) substrates compared to previous approaches.

The device may have an array of first regions in which the second layer is of opposite doping type to that of the first layer and forms p-n junctions in these first regions, and second regions, each second region containing the barrier layer and the reflector layer. The first and second regions are laterally intermixed and have a lateral shape of either bounded regions or stripes, or a combination of bounded regions and is stripes. The distance between centers of any two adjacent first regions is less than one minority carrier diffusion length in the second semiconductor layer to optimize carrier collection efficiency.

### BRIEF DESCRIPTION OF THE DRAWINGS

FIG. 1 shows a cross-section of an embodiment of a photovoltaic device.

FIG. 2 shows a plan view of an embodiment of a photovoltaic device.

FIGS. 3A-3G show a series of cross-sections illustrating a process for making a photovoltaic device.

### DETAILED DESCRIPTION OF THE INVENTION

Following common practice, the drawings are not necessarily drawn to scale. Some relative sizes have been exaggerated in order to better describe the invention.

FIG. 2 shows a plan view of a first embodiment of a front-surface-illuminated photovoltaic device. An array of first regions 115 is laterally intermixed with second regions 300 where, in this embodiment, second regions 300 are the space between first regions 115. The first regions 115 have the shape of a square. Alternatively, first regions 115 could have the shape of any closed, bounded regions, such as polygons or circles, or they could be stripes extending laterally across the device. First regions 115 could also have varied shapes over the device, such as a mixture of bounded regions and stripes. In this embodiment the first regions 115 (and concurrently second regions 300) are defined by holes formed through multiple layers, as explained in more detail below. FIG. 2 shows a corner of the device; first regions 115 extend in two dimensions laterally over the device, as indicated by the triplets of dots.

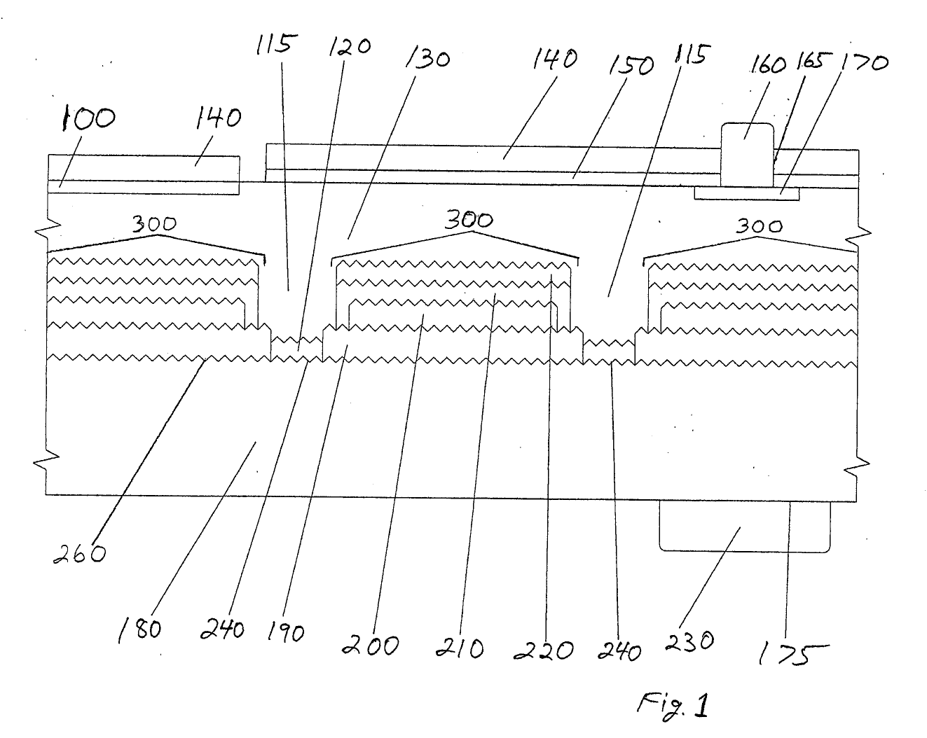

FIG. 1 shows a cross section of the structure of a first embodiment of a front-surface-illuminated photovoltaic device. The cross section is taken along the line A-B in s FIG. 2. The device structure contains the following elements: a first semiconductor layer, or substrate 180 with a back surface; a second semiconductor layer, or absorber layer 130, of doping type opposite to that of substrate 180 and having a front surface; a barrier layer 190 in contact with the substrate 180; a reflector layer 200 in contact with the barrier layer 190, at least one front-surface ohmic contact 160 for electrical contact to the absorber layer 130, and at least one back surface ohmic contact 230 for electrical contact to the substrate 180.

Still referring to FIG. 1, the first regions 115 contain essential p-n junctions 240 for operation of the photovoltaic device. The p-n junctions 240 may be formed at the junction between the substrate 180 and the oppositely doped absorber layer 130. Optionally, as in the embodiment in FIG. 1, a semiconductor blocking layer 120 may be situated between the substrate 180 and the absorber layer 130 for blocking diffusion of impurities from the substrate 180 into the absorber layer 130. Blocking layer 120 enables the use of a lower impurity (hence less expensive) material for the substrate 180. Blocking layer 120 may be of the same doping type as substrate 180, in which case the p-n junction 240 is formed at the junction between blocking layer 120 and absorber layer 130. Alternatively, blocking layer 120 may be of opposite doping type as substrate 180 (same doping type as absorber layer 130), in which case p-n junction 240 is formed at the junction between blocking layer 120 and substrate 180.

In an alternative embodiment, blocking layer 120 is not confined to first regions 115, as in FIG. 1, but extends into second regions as well, or extends laterally over the entire device. Blocking layer 120 could be a layer of semiconductor with thickness up to about 10 microns, and it would be the same doping type as the substrate. Blocking layer 120 would be used to improve the electronic properties of the substrate by creating a surface layer or “denuded zone” that is relatively free of defects such as impurities and dislocations that may be present in a highly conductive silicon substrate 180. The resistivity of blocking layer 120 can be adjusted to optimize the p-n junction formed between substrate 180 and absorber layer 130. Blocking layer 120 could be used to block impurities that might diffuse from the substrate into the subsequently deposited layers and to reduce surface defects that are found on the top surface of substrate 180. Blocking layer 120 could be used to terminate dislocations that could propagate from grain boundaries or other defects if substrate 180 is polycrystalline.

Continuing with the embodiment of FIG. 1, second regions 300 contain barrier layer 190 and reflector layer 200. Barrier layer 190 acts as a barrier to diffusion of impurities from substrate 180 into the rest of the device. As with blocking layer 120, barrier layer 190 may enable the use of a lower impurity (hence less expensive) material for the substrate 180. Reflector layer 200 acts to reflect photons entering the front surface back into absorber layer 130 if those photons penetrate all the way to the reflector layer 200 without being absorbed in the absorber layer 130. The presence of reflector layer 200 may therefore increase the efficiency of the device by making it more likely that a photon will be absorbed in absorber layer 130, thus producing more electron-hole pairs that can be collected and contribute to the generated current.

As an option, as shown in the embodiment in FIG. 1, there may be an internal passivation layer 210 at least partially encapsulating reflector layer 200 in second regions 300. Internal passivation layer 210 is meant to prevent diffusion of the material of reflector layer 200 into the rest of the device. In the embodiment shown in FIG. 1, passivation layer 210 and barrier layer 190 completely encapsulate reflector layer 200, with passivation layer 210 wrapping around the edges of reflector layer 200. Alternatively, passivation layer 210 may at least partially encapsulate barrier layer 190 by extending over the edges of barrier layer 190. Alternatively, if the material of reflector layer 200 is unlikely to diffuse significantly into the rest of the device during the processing of the device, internal passivation layer 210 may be omitted.

The device may have front passivation on the front surface to reduce recombination over the front surface and, in general, stabilize the electrical characteristics of the device. The front passivation may be made of at least one of the following: a front passivation layer 150, a floating p-n junction 100, or a heteroface. A heteroface is an electrical junction between dissimilar semiconductor materials. It could be formed, for example, by deposition of n-type GaP on the top surface of a p-type silicon absorber layer 130. Floating junction 100 may be formed by diffusion of dopant into absorber layer 130, the dopant of opposite type to that of absorber layer 130.

The device may have an anti-reflection coating 140 covering front passivation layer 150 and floating junctions 100. Anti-reflection coating 140 decreases the fraction of incident light reflected from the front surface and therefore improves overall conversion efficiency of the device.

Electrical contact is made to the device using at least one front ohmic contact 160 to absorber layer 130 and at least one back ohmic contact 230 to substrate 180. An additional doping layer (not shown) may be added to substrate 180 at back contact interface 175 to decrease contact resistance. Alternatively, separate doping for the back contact 230 may not be required; the doping of the substrate 180 may be sufficiently high to give an ohmic contact without additional doping at interface 175. In one embodiment the doping of the substrate can be as high as it needs to be to get good ohmic contact with the deposited back contact metal 230. There would not be a need for a diffused or alloyed layer at the interface 175. For the front ohmic contact 160, additional doping layer 170 may be formed in absorber layer 130 to reduce recombination at the front contact. For example, if the absorber layer 130 is n-type, an n+ layer may be fabricated under the contacts. Front passivation layer 150, a heteroface, or a floating junction 100 reduces recombination across the rest of the front surface.

The front contact 160 may be buried. In an embodiment in which internal passivation layer 210 is not present, and reflector layer 200 is a good electrical conductor, such as a metal, an electrical connection may be established from front metal contact 160 to reflector layer 200 by using a heavily doped vertical layer (not shown). Seed layer 220 on top of reflector layer 200, if present, as disclosed below, could be heavily doped to reduce recombination.

Substrate 180 has a thickness in the range of about 100 to about 500 micrometers, sufficient to provide mechanical support. Substrate 180 can be doped either p-type or n-type. It may be composed, entirely or partially, of silicon, Si. As one example, p-type semiconductor grade silicon is abundant, and an n-type layer on a p+ substrate has the advantage that an n-layer is generally more tolerant of electrical defects. Other suitable material for substrate 180 include: a mixture of silicon and another semiconductor material with a higher melting point than silicon, such as silicon carbide, SiC; metallurgical grade silicon; or a thin Si layer on steel, which provides enhanced flexibility and electrical contact conduction. Substrate 180 may be cast from molten semiconductor using known ceramic and metallurgy techniques. It may be given a textured surface to promote light trapping, described in more detail below.

Barrier layer 190, reflector layer 200, and internal passivation layer 210 add up to a total thickness between about 0.1 and about 0.5 micrometers. Barrier layer 190 material may be a nitride of silicon, an oxide of silicon, an oxide of aluminum, aluminum nitride, tungsten carbide, titanium carbide, or silicon carbide. Reflector layer 200 should have high reflectivity at light wavelengths close to the bandgap absorption wavelengths of the semiconductor material of absorber layer 130. Reflector layer 200 may be a metal or a non-metal. If absorber layer 130 is primarily silicon, appropriate metals for reflector layer 200 include nickel, silver, chrome, palladium or any combination thereof. Appropriate non-metals include titanium nitride, boron carbide, silicon carbide, or any combination thereof. Internal passivation layer 210 may be a nitride of silicon, an oxide of silicon, a carbide of silicon, or any combination thereof. Internal passivation layer 210 may also be a wide bandgap material, such as silicon carbide (SiC) which may form a high-low semiconductor junction with seed layer 220 or directly with absorber layer 130.

The thickness of absorber layer 130 in this embodiment is between about 5 and about 50 micrometers.

Front passivation layer 150 may be made of amorphous silicon, a nitride of silicon, or an oxide of silicon, or a combination of these.

Anti-reflection coating 140 may have a single layer or multiple layers of materials which are at least partially transparent to light in the range of wavelengths from the infra-red through the ultraviolet and which have appropriate indices of refraction and thicknesses. Suitable materials include, but are not limited to, a nitride of silicon, an oxide of titanium, an oxide of tantalum, an oxide of aluminum, an oxide of silicon, or any combination thereof.

In operation, photons enter the device through the front surface. Photons may be is absorbed directly in absorber layer 130. Some photons, especially those of longer wavelength, may pass completely through absorber layer 130 to reflector layer 200 without being absorbed. They may then be reflected back into absorber layer 130 and absorbed. If substrate 180 has a textured surface 260, reflector layer 200 may also have a textured surface, and photons striking reflector layer 200 will be scattered as well as reflected, increasing the optical path length and the likelihood of absorption in absorber layer 130. Photons may also pass through to textured surface 260 of substrate 180 in the first regions 115 where they are scattered back into absorber layer 130 and then absorbed. Once a photon is absorbed, an electron-hole pair is formed and the two carriers thermally diffuse. Carriers reaching depletion regions of p-n junctions 240 will be swept out, or collected, by the built-in electric fields of junctions 240 and contribute to external photocurrent.

For good efficiency of carrier collection, distances between openings defining first regions 115 should be small enough that carriers are collected before they recombine. One way this may be achieved is to make lateral distance between centers of any two adjacent first regions 115 less than one minority carrier diffusion length in absorber layer 130. In general, the distance between openings defining first regions 115 and/or the sizes of the openings may be chosen to optimize efficiency for a given diffusion length (or carrier lifetime) in absorber layer 130. For a silicon device, it is expected that the distance between centers of first regions 115 will fall in the range from about 2 to about 1000 micrometers, and the width of first regions 115 is expected to fall in the range from about 1 to about 50 micrometers.

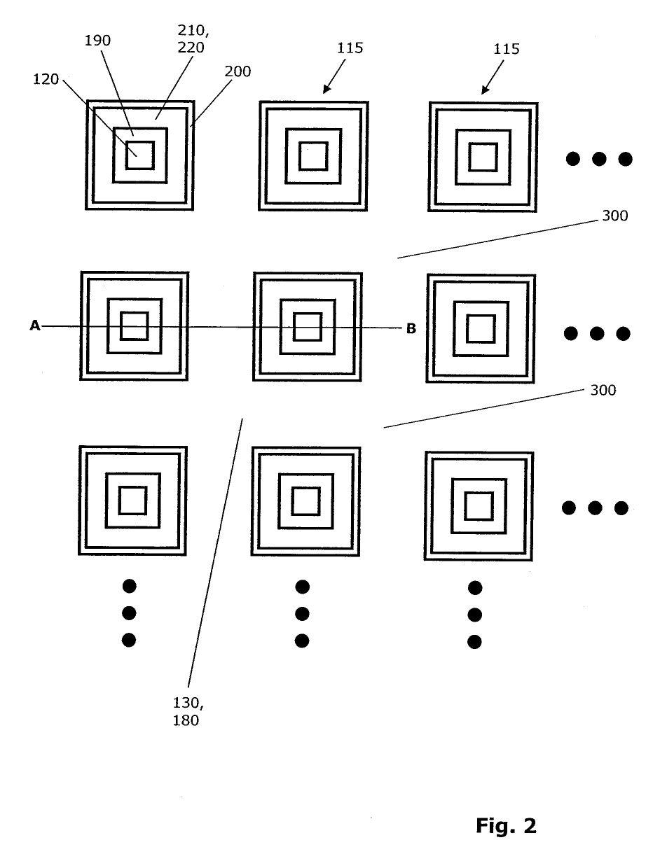

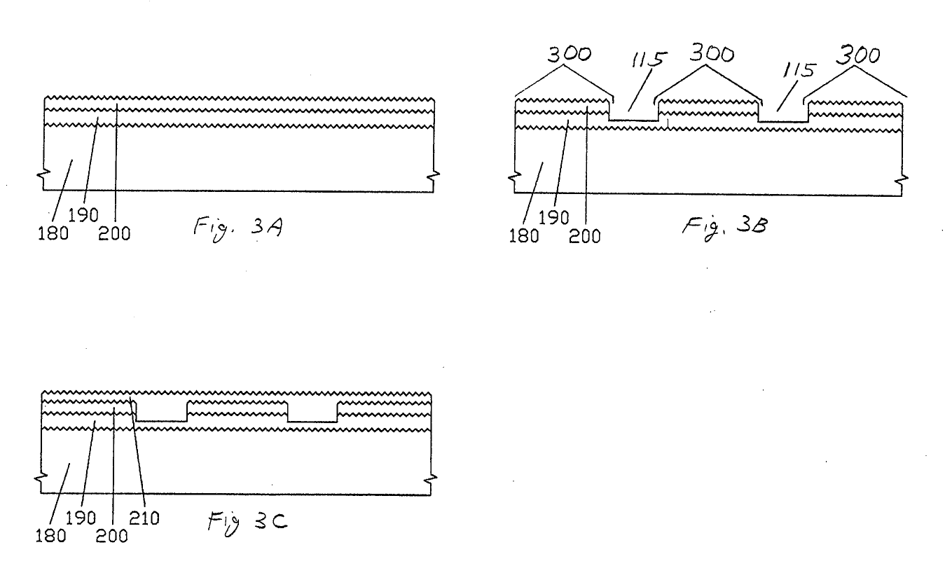

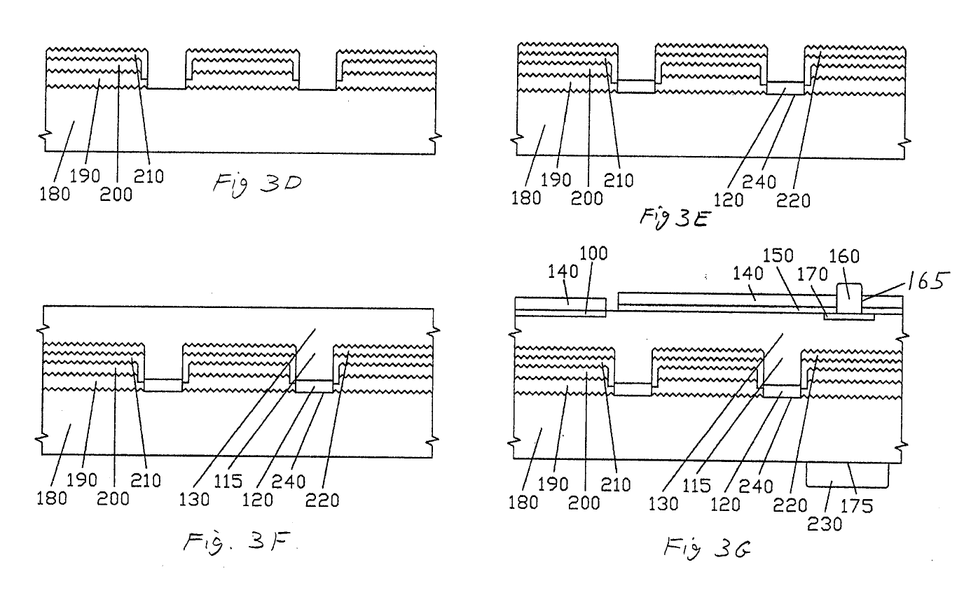

FIGS. 3A-G show an embodiment of a process method for fabricating the embodiment of a solar photovoltaic device shown in FIGS. 1 and 2.

FIG. 3A shows the device structure after the steps of obtaining a semiconductor substrate 180 of a first doping type with a top and bottom surface; forming barrier layer 190 on the top surface; and depositing reflector layer 200 on barrier layer 190. Prior to the forming of barrier layer 190, substrate 180 may be textured to enhance light scattering from the top surface of substrate 180 back into absorber layer 130, as disclosed above. The texturing can be achieved by texturing a mold in which substrate 180 is cast. Alternatively, texturing may be achieved by forming a mixture of the semiconductor material of substrate 180 and particles of a second semiconductor having a melting point higher than that of the material of substrate 180; heating the mixture to a temperature above the melting point of the first semiconductor and below the melting temperature of the second semiconductor, and cooling the mixture below the melting point of the first semiconductor. The particles impart texture to substrate 180. As a specific example, the first (substrate 180) semiconductor is silicon, the second semiconductor is silicon carbide (SiC), and the proportion of silicon carbide, by volume, is in the range from about 1% to about 90%. The particles may have sizes in the range from about 0.1 to about 1.0 micrometers. The texturing is configured so as to scatter light in the wavelength range from the infrared to the ultraviolet.

Barrier layer 190 and reflector layer 200 may be formed using any known deposition technique including, but not limited to, APCVD, LPCVD, PECVD, MOCVD, or other chemical vapor deposition methods; evaporation; sputtering; spray pyrolysis; or printing. Barrier layer 190 may be formed using thermal oxidation.

FIG. 3B shows the structure after a step of forming a plurality of openings through reflector layer 200 and barrier layer 190. The openings define a plurality of first regions 115 and the spaces separating the openings define second regions 300. The openings may be formed using known techniques including, but not limited to, wet chemical etching; dry etching, such as plasma etching; laser machining; air abrading; or water blasting. If the surface of substrate 180 is textured, openings may be formed through thinning layers on surface-textured peaks: the reflector and barrier layers will be thinner over the peaks of the texture than over the valleys, and these thinner regions can be etched away, exposing the underlying substrate 180, while leaving the substrate 180 covered in the thicker regions. Some of these methods, such as wet or dry etching, may require a masking step, such as photolithography using photoresist. Others, such as laser machining, may not require a masking step.

FIG. 3C shows the structure after a step of depositing internal passivation layer 210 covering reflector layer 200. Passivation layer 210 may be deposited using chemical vapor deposition, sputtering, spray pyrolysis, or printing.

FIG. 3D shows the structure after completion of a step of completing the forming of openings defining first regions 115 by forming a plurality of openings in internal passivation layer 210 coinciding with the openings defining the first regions, such that the remaining internal passivation layer 210 at least partially encapsulates the reflector layer 200 at edges of the second regions. A patterned photoresist layer may be used to define the areas to be etched. Alternatively, barrier layer 190 may be partially encapsulated by passivation layer 210 as well. In this step the top surface of substrate 180 is exposed. Openings in passivation layer 210 may be formed using any of the techniques disclosed above in connection with FIG. 3B.

FIG. 3E shows the structure after completion of a step of forming semiconductor blocking layer 120 and semiconductor seed layer 220. Blocking layer 120 and seed layer is 220 may be formed simultaneously or separately. They may be formed simultaneously in a deposition step that deposits semiconductor simultaneously in first regions 115 over substrate 180 and in second regions over passivation layer 210.

Blocking layer 120 may be formed separately in an alternate embodiment in which blocking layer 120 is deposited directly on substrate 180 before forming of barrier layer 190. In this embodiment, forming of openings defining first regions 115 is done so that the openings terminate at blocking layer 120.

Alternatively, either one or both of blocking layer 120 and seed layer 220 may be omitted, depending on properties of substrate 180, such as impurity content and degree of crystallinity.

FIG. 3F shows the structure after a step of depositing semiconductor absorber layer 130 covering first regions 115 and second regions 300 and forming p-n junctions 240 inside the openings defining first regions 115. Seed layer 220 acts to initiate growth of absorber layer 130. Depositing the semiconductor layer may be carried out by depositing a layer of dry semiconductor powder. The dry powder may be optically sintered before crystallization. Alternatively, depositing the semiconductor layer may be carried out by depositing a wet semiconductor slurry. In yet another embodiment, depositing the semiconductor layer may be carried out using chemical vapor deposition (CVD). As one example, trichlorosilane may be used in the CVD step to deposit silicon absorber layer 130. Prior to CVD deposition, substrate 180 may be cleaned using known techniques, such as an etch with HCl. This step could be done in-situ in a CVD reactor.

Absorber layer 130 may have acceptable electronic properties as deposited. Alternatively, absorber layer 130 may be formed by depositing a semiconductor layer and recrystallizing the deposited layer. Recrystallizing may be carried out using known techniques alone or in combination, including, but not limited to, a moving strip heater, or an optical source such as a laser or flashlamp. Recrystallization could take place in a reducing atmosphere, such as hydrogen plus argon, to prevent oxide formation during this step.

FIG. 3G shows the structure after the steps of forming one or more ohmic contacts to absorber layer 130 and to substrate 180; also front passivation layer 150, floating junction 100, and anti-reflection coating 140. Ohmic contact to absorber layer 130 contains metal 160 and additional doping layer 170 in absorber layer 130 to reduce recombination. Doping layer 170 may be formed by diffusion, ion implantation, or other known techniques. Ohmic contact to substrate contains metal 230 in contact with substrate 180 at back contact interface 175. Optionally, additional doping may be introduced at interface 175, similar to layer 170. Ohmic contacts to absorber layer 130 may be formed by depositing passivation layer 150 and anti-reflection coating 140, then forming openings 165 through both of these layers. Metal 160 is deposited and patterned using known techniques. Alternatively, forming ohmic contacts to absorber layer 130 may include screen printing metal 160, such as silver, on front passivation layer 150 and firing the metal through passivation layer 150. Alternatively, metal 160 may be fired through anti-reflection coating 140 if metal 160 is applied before contact openings 165 are formed.

Front passivation layer 150 may be deposited using any of the deposition techniques disclosed above in the description of FIG. 3A. Front passivation layer 150 may form a heteroface (an electrical junction between dissimilar semiconductor materials) with absorber layer 130.

Before deposition of passivation layer 150, the front surface of absorber layer 130 may be textured, either mechanically, chemically, or with a combination of these methods, to reduce front surface reflectance.

In an alternative embodiment, the device has substrate 180, absorber layer 130 of opposite doping type to the substrate 180 and deposited on substrate 180, at least one ohmic contact 160 to the absorber layer, at least one ohmic contact 160 to absorber layer 130 and at least one ohmic contact 230 to substrate 180. As in previously described embodiments, this embodiment may also have front passivation, single- or multiple-layer antireflection coating, and textured surfaces on the substrate and absorber layers. Materials for these structures and methods for making this device may be as previously disclosed.

Although the invention is illustrated and described herein with reference to specific embodiments, the invention is not intended to be limited to the details shown. Rather, various modifications may be made in the details within the scope and range of equivalents of the claims and without departing from the invention.

1. A front-surface-illuminated photovoltaic device, comprising: a first semiconductor layer with a back surface; a second semiconductor layer with a front surface, a barrier layer, configured to reduce diffusion of impurities from the first semiconductor layer into the second semiconductor layer, the barrier layer being in contact with the first semiconductor layer, a reflector layer in contact with the barrier layer, and at least one ohmic contact to each of the first and second semiconductor layers.

2. The device of claim 1, further comprising: a plurality of first regions wherein the second layer is of opposite doping type to that of the first layer and forms p-n junctions in the first regions, and a plurality of second regions, each second region comprising the barrier layer and the reflector layer, the first and second regions being laterally intermixed, and having a lateral shape of either bounded regions or stripes, or a combination of bounded regions and stripes.

3. The device of claim 1 further comprising front passivation made of at least one of: a front passivation layer, a heteroface, and a floating junction, in contact with the front surface.

4. The device of claim 3, wherein the front passivation layer comprises amorphous silicon, a nitride of silicon, or an oxide of silicon, or a combination of these.

5. The device of claim 3 further comprising an anti-reflection coating in contact with or proximal to the front surface.

6. The device of claim 2, wherein distance between centers of any two adjacent first regions is less than one minority carrier diffusion length in the second semiconductor layer.

7. The device of claim 1, further comprising a semiconductor blocking layer situated between the first and second semiconductor layers, the blocking layer configured so as to block the diffusion of impurities from the first layer into the second layer.

8. The device of claim 2, further comprising an internal passivation layer at least partially encapsulating the reflector layer in the second regions.

9. The device of claim 8, wherein the internal passivation layer at least partially encapsulates the barrier layer.

10. The device of claim 1, wherein either the first layer or the reflector layer or both have textured surfaces so as to scatter light in the wavelength range from the infrared to the ultraviolet into the second layer.

11. The device of claim 10, wherein the first layer further comprises particles, the particles giving rise to the texture.

12. The device of claim 11, wherein the first and second layers comprise silicon and the particles comprise silicon carbide.

13. The device of claim 1, wherein the first and second semiconductor layers comprise silicon.

14. The device of claim 13, wherein the first layer comprises one of: metallurgical-grade crystalline silicon, semiconductor grade crystalline silicon, silicon on steel, polycrystalline silicon, or amorphous silicon.

15. The device of claim 1, wherein the barrier layer comprises a nitride of silicon, an oxide of silicon, an oxide of aluminum, aluminum nitride, tungsten carbide, titanium carbide, or silicon carbide.

16. The device of claim 1, wherein the reflector layer comprises a metal.

17. The device of claim 1 wherein the reflector layer is in electrical contact with the second semiconductor layer and forms part of the ohmic contact to the second semiconductor layer.

18. The device of claim 16, wherein the reflector layer comprises nickel, silver, chrome, or palladium.

19. The device of claim 1, wherein the reflector layer is a non-metal.

20. The device of claim 19, wherein the non-metal comprises titanium nitride, boron carbide, or silicon carbide.

21-73. (canceled)
